(19) United States
(12) Patent Application Publication
(10) Pub. No.: US 2008/0212045 A1
(43) Pub. Date: Sep. 4, 2008

(54) OPTICAL SYSTEM WITH AT LEAST A SEMICONDUCTOR LIGHT SOURCE AND A METHOD FOR REMOVING CONTAMINATIONS AND/OR HEATING THE SYSTEMS

(75) Inventor: Dieter BADER, Obergroeningen (DE)

Correspondence Address: SUGHRUE MION, PLLC, 2100 PENNSYLVANIA AVENUE, N.W., SUITE 800, WASHINGTON, DC, 20037, US

(73) Assignee: Carl Zeiss SMT AG, Oberkochen (DE)

(21) Appl. No.: 11/970,456

(22) Filed: Jan. 7, 2008

Related U.S. Application Data
(63) Continuation of application No. PCT/EP2006/006441, filed on Jul. 3, 2006.

(30) Foreign Application Priority Data
Jul. 7, 2005 (DE) 102005031792.8

(51) Int. Cl. G03F 7/20; G21G 5/00

(52) U.S. Cl. 355/30; 250/492.1; 355/67

(57) ABSTRACT

A method for removing contaminations from optical elements or parts thereof, especially from at least one surface of at least one optical element, with UV light. At least one semiconductor light source is used for removing the contaminations, wherein the semiconductor light source is arranged in and/or on a support of the optical element and/or close to the optical element such that a light of the semiconductor light source impinges onto the surface of the optical element.

### REFERENCE TO RELATED APPLICATIONS

This is a Continuation of International Application PCT/EP2006/006441, with an international filing date of Jul. 3, 2006, which was published under PCT Article 21(2) in English, and the disclosure of which is incorporated into this application by reference. This application claims priority and benefit of German patent application 10 2005 031 792.8, filed Jul. 7, 2005. The disclosure of this application is also incorporated herein in its entirety.

### FIELD OF THE INVENTION

The invention relates to a method for removing contaminations from optical elements, especially from at least one surface of an optical element and/or a method of heating an optical element, as well as an optical system with a semiconductor light source.

### BACKGROUND OF THE INVENTION

The contamination of optical elements still represents a serious problem. Especially this problem arises in optical systems used in microlithography, such as a projection exposure apparatus. Contamination consistently impairs the quality of the projection exposure system containing the optical elements. Known projection exposure systems for example work with wavelengths ≦193 nm, especially in the range ≦157 nm, especially in the EUV range with wavelengths ≦30 nm, especially <13 nm. The problem with projection exposure systems using such wavelength is that the radiation in the EUV, VUV and DUV range leads to a contamination and/or destruction of the optical surface of the components, which are also designated as optical elements.

Especially the first and last optical surfaces of refractive systems for example can contaminate because they are situated in the direct vicinity of a light source, a mask or a wafer to be exposed for example. Impurities can thus be introduced into the optical system. It is thus common practice to protect these occluding surfaces by pellicles for example, i.e. thin films. Such films lead to the absorption of light and might contribute to image defects (aberrations) in the optical system. Due to the image defects the uniformity e.g. in a field plane a microlithography exposure apparatus and/or the ellipticity and/or telecentricity in a pupil plane can be influenced in a negative manner.

High-energy radiation from a light source in the range of ≦193 nm for example furthermore leads to the consequence that residual oxygen shares are converted by radiation into ozone for example, which on its part attacks the surfaces of the optical elements (i.e. their coating) and can destroy them. The residual gas concentrations such as hydrocarbons in the ambient atmosphere can lead to the formation of contaminations on the optical surface, e.g. by formation of crystals or layers of carbon or carbon compounds. It is assumed that as a result of the high-energy radiation, carbon-containing molecules, which are present for example on the surfaces of the optical elements in an adsorbed manner, are converted into more reactive species either directly by the high-energy radiation or via formed free electrons, which reactive species form stronger bonds with the surface and can increasingly aggregate.

A contamination leads to a reduction of the reflection in the case of reflective components and to a reduction of the transmission in the case of transmissive elements. Contaminations can cause up to 5% of absorption losses for example in an optical element. The contamination depends on the illumination level. The thermal load, i.e. the heating, is especially high in such optical components which are subject to a high radiation exposure.

It is known to remove carbon or carbon compounds by regular cleaning of mirrors, e.g. by admixing argon and oxygen under an RF-plasma. Reference is hereby made to the cleaning of contaminated optical systems to: F. Eggenstein, F. Senf, T. Zeschke, W. Gudat, “Cleaning of contaminated XUV optics at Bessy II”, Nuclear Instruments and Methods in Physics Research A 467-468 (2001), p. 325-328, the scope of disclosure of which is fully included in the present patent.

In the mounting of illumination systems, several cleaning steps are usually made for removing the mentioned organic contaminations. The modules and individual lenses are irradiated for example with a special UV burner. Despite this cumbersome cleaning it is necessary to clean the entire system prior to start-up again with a laser, which is known as so-called “burn-off”. This burn-off substantially has an effect on the uniformity (“roll-off”) and the transmission of the cleaned modules or optical components.

Proposals have already been made in the state of the art which deals with the removal of contaminations:

A method is disclosed in US 2001/0026402 A1 for the decontamination of microlithography projection exposure systems with optical elements or parts thereof, especially for surfaces of optical elements with UV light and fluid, with a second UV light source being directed against at least a part of the optical elements during exposure breaks. A broadband laser is used for example as a cleaning light source. For removing detached contamination components from the closed optical system a flow of a fluid such as an ozone- or oxygen-containing is guided parallel to the surfaces of the optical elements to be cleaned or along the same.

The state of the art in accordance with U.S. Pat. No. 6,268,904 B1 further discloses an optical exposure apparatus and an optical cleaning method. A photo-cleaning unit for improving either the degree of transmission or the degree of reflection of at least one optical element. The photo-cleaning unit is configured for optically cleaning a surface of at least one of a plurality of optical elements and is arranged in the optical exposure apparatus preferably between the light source and the photo-sensitive substrate. According to an especially preferred embodiment, a photo-cleaning light source is provided separate from the excitation light source. It is especially preferable to use a light source whose wavelength is close to the illumination wavelength. An ArF laser or an optical illumination apparatus which uses EUV light such as soft X-rays with a short wavelength can be used for example as an illumination light source.

The problematic aspect in the described decontamination process or in the above final cleaning step (the so-called “burn-off”) is that after the installation only very limited areas of an optical element can usually be cleaned and this can occur only depending on the setting and field size.

An additional problem is the uneven and decreasing irradiance, especially when only one light source is provided for several optical components to be cleaned and the distance to the light source increases, i.e. the radiation intensity per surface area decreases. In addition to the insufficient cleaning of the overall surface area, the light will then also not have the necessary intensity for effective cleaning.

Optical elements with a large diameter thus still represent a larger problem. This applies especially to lenses with a large diameter which have a low irradiance and thus allow only very adverse cleaning. This also applies especially to optical elements with a large radius of curvature. These elements usually have the problem of contamination at the edge. The cause for this is the coating process. The coating at the edge is more porous and can thus be contaminated more easily.

Further methods for cleaning optical elements, especially surfaces of optical elements have made known from DE10240002A1 and DE1021161A1.

The usage of semiconductor light sources especially UV laser diodes in microlithography exposure system have been made known from US 2002/01264-79, U.S. Pat. No. 6,233,039, DE10230652A1 and WO99/45558. In all aforementioned documents the semiconductor light sources were used in the microlithography exposure apparatus for the photolithographic process itself; meaning that the light of the semiconductor light source is used to expose a photosensitive surface and not as a additional light source, e.g. a additional compensating light source.

From WO03/096387 a light module with a micro array of semiconductor light sources have been made known. The light module can also be used for debris removal and other photochemical processes. The light module is not part of an optical component or optical element.

An even further problem of the optical system especially for use in a microlithography exposure apparatus is the lens heating of the optional elements, which lead to image errors.

Regarding lens heating reference is made to U.S. Pat. No. 5,805,273. and U.S. Pat. No. 6,504,597.

In U.S. Pat. No. 5,805,273 is described how by temperature adjusting devices an asymmetric temperature distribution within a lens element or elements of a projection lens can be prevented.

In U.S. Pat. No. 6,504,597 a compensating light supply device is described, with which a lens heated by optically coupling in the light of the compensating light device via e.g. a fibre to different locations of the optical element. As a light source for the compensating light supply device a light source with an emission wavelength greater than 4 μm is used. Lens heating is a most serious problem if highly asymmetric illuminations such as dipole illuminations in a pupil and/or off-axis field illuminations are employed in a microlithography exposure system.

### SUMMARY OF THE INVENTION

According to a first aspect of the present invention a method for removing contaminations from an optical element or an optical system or partial system is provided. With the inventive method the disadvantages of the state of the art are avoided and contaminations can be removed in the individual optical element in an optical system in exposure operation or in exposure operation breaks, without any likelihood of damage the surface, coatings or materials of the optical element or the optical system.

This first aspect of the invention is achieved by the method as mentioned in claim 1.

The method in accordance with the invention provides using at least one semiconductor light source for removing contaminations of optical elements or parts thereof, especially of at least one surface of an optical element.

“Semiconductor light sources” shall be understood as high-performance light sources, with the disturbing heat emission of the light source being excluded A semiconductor light source emits light with a strongly reduced share of infrared light and can also be designated as a “cold light source”. Infrared light is light with wavelengths between 780 nm and 1 mm. A cold light source is used where light of the highest intensity in the visual spectral range is required, but where the development of heat of a conventional light source would be disturbing or even damaging. This is in complete contrast to conventional light sources such as Hg I line vapor discharge lamps which show a high unspecific heat development.

A further subject matter of the invention is also an optical system or a partial system comprising at least one optical element and one or several semiconductor light sources for irradiating at least one surface of the optical element. Preferably the semiconductor light source is arranged in and/or on a support of the at least one optical element. Most preferably the light of the semiconductor light source impinges onto the at least one surface of the at least one optical element.

The optical system as described above is especially used for cleaning an optical element or parts thereof, especially for at least one surface of an optical element.

According to a further aspect of the invention the semiconductor light source is used for heating an optical element e.g. lens in specific areas in order to avoid or compensate image errors and/or aberrations.

According to even a further aspect of the invention a projection system for imaging an object into an image comprising a semiconductor light source is provided. The projection system can be a projection objective comprising a plurality of refractive optical elements as described in U.S. Pat. No. 6,665,126 or a projection objective comprising a plurality of reflective elements as disclosed in U.S. Pat. No. 6,902,283.

According to a further aspect of the invention a method for compensating images errors and/or aberrations is provided. These errors are due to the fact that e.g. in a projection system some lenses or mirrors are illuminated in a non-rotational symmetric manner by the imaging light bundle traveling from an object side to an image side and imaging an object in the object plane into an image in the image plane. The light bundle creates on the surface of the lens or the mirror a so called footprint, which corresponds to the area that is illuminated by the light of the bundle. Non rotational symmetric footprints create a non rotational heating of the lens or mirror. Such a non-rotational symmetric footprint is caused e.g. by a dipolar illumination of a pupil in a projection lens, especially for lens elements which are situated close to the pupil plane. The non rotational symmetric heating by the imaging light bundle which images an object in an object plane into an image in a image plane creates image errors and aberrations and can lead to a destruction of the optical element. By selectively heating the lens or mirror by the additional semiconductor light source or light sources a rotational symmetric heating can be provided and thus image errors can be compensated. A selective heating of the lens or the optical element can be achieved with semiconductor light sources according to the invention. By absorbing the radiation of the semiconductor light source a selective heating of selected areas can be achieved as described. For example by external heat applied by absorbing light emitted by the semiconductor light source to a peripheral portion of a lens having a lower temperature, a rotational symmetric temperature distribution with respect to the optical axis of the lens can be provided.

The invention will be described below in detail, with the disclosure for the method applying analogously to the optical system or partial system and vice-versa:

The semiconductor light sources in accordance with the invention are not especially limited within the scope of the invention. Especially preferably used are so-called UV-LEDs or also UV laser diodes, laser diodes, e.g. combined with diffractive or refractive optical elements for beam formation, diode arrays or the like. UV light comprises wavelength smaller than 380 nm. Preferably the wavelength of UV light is between 100 nm and 380 nm.

Such semiconductor light sources like UV-LEDs offer sufficient output in order to easily remove the mentioned contaminations without virtually any residue, but without impairing or changing the surface, possible coatings or the like in any way.

Furthermore they provide for sufficient light which can be absorbed by the optical elements in order to heat the optical elements in selected areas. UV-LEDs are light sources which are known for long service life, intensity that is easy to regulate, adjustable intensity (current-controlled), random arrangement, random configuration, fixed spectrum (no filter necessary) and defined radiating characteristics.

Especially preferred UV-LEDs are: i-LEDs and UV-LEDs with shorter wavelengths.

The term “LED” shall be understood within the scope of the invention not only as the conventional design with a glass body, but also as the pure mounting of the so-called “chip dies” on metal or ceramic substrate. These chip dies are LEDs which are bonded in a tight package, e.g. on a ceramic substrate. They are distributed for example by Roithner Laser as units of 66. A die usually has a size of approximately 300 μm×300 μm. It is thus no problem to house approximately 1000 chips on the smallest possible surface area, e.g. on the lamp-holder edge of an optical element. There are a number of firms that have specialized in the processing of LED chips in any desired arrangement.

According to a preferred embodiment, one or several semiconductor light sources are arranged in and/or on a support of at least one optical element and/or close to at least one optical element in such a way that the UV light meets the surface of the optical element, and especially irradiates the same in a substantially even or uniform manner. A combination is further possible of semiconductor light source(s), e.g. LED and/or UV laser diode, and at least one optical element such as a DOE (diffractive optical element), an ROE (refractive optical element) or a CGH element (computer generated hologram; a diffractive optical element) in order to achieve an individual distribution of intensity optimized for the optical surface for cleaning and/or heating.

In addition to a homogeneous distribution of the intensity of the radiation sources used in accordance with the invention, it can also be advantageous when an inhomogeneous distribution of intensity is used in a purposeful manner. This is useful in cases when more contaminations accumulate at the edge of the lens or if the lens is additional heated in order to compensate e.g. a non-rotational symmetric heating and therefore image errors.

In accordance with the invention, only the same or equivalent semiconductor light sources can be used for example, which means that only UV laser diodes of a certain type are used or combinations of different semiconductor light sources of one type or different types can be used in combination with one another such as different types of UV laser diodes having different output capacities or characteristics. Alternatively, UV laser diodes and UV LEDs can be used in an alternating manner or arranged in groups. It is understood that any other combinations are possible for the respective application.

A removal of contaminations and/or heating can occur irrespective of the illumination mode of the optical system or partial system in which the optical element is used. “In the vicinity” shall mean a spatial arrangement which allows irradiating one or several optical elements with the light of the semiconductor light source with a suitably high intensity in such a way that a removal of the contaminations of the irradiated surface is achieved. Several semiconductor light sources are preferably used, which are provided in a suitable arrangement in and/or on a support of at least one optical element.

The position of the semiconductor light source(s) in and/or on the support is not especially limited insofar as a sufficient decontamination of the optical element is achieved. For example, UV LEDs can be integrated in a support of one or several optical elements or they can be attached alternatively or additionally on or in the support.

A support can be arranged in any desired way, be of an integral or multi-part configuration, and hold or carry the optical element on one or several areas. The support can enclose the optical element partly or completely and can have a symmetrical or asymmetrical configuration. This depends on the type and shape of the optical element and the optical system or partial system in which the optical element is used.

The one or several semiconductor light sources can be arranged in a stationary or movable manner, e.g. they can be displaceable or rotating, so that either several surface areas of an optical element are covered with one or several semiconductor light sources or several optical elements can be irradiated, e.g. at first a surface of an optical element and thereafter another surface of an optical element by turning.

The number of semiconductor light sources can be adjusted to the optical element to be cleaned, e.g. to the expected and measured degree of contamination, the expected and measured degree of compensation of image errors, the shape and size of the optical element, the type and strength of the illumination radiation used during the application of the optical element, and a number of other factors known to the person skilled in the art.

The arrangement of the semiconductor light sources is preferably chosen in such a way that at least one surface of the optical element to be cleaned is irradiated nearly completely and is thus cleaned. Especially the boundary areas of the optical elements which are not reached with light sources such as lasers as known from the state of the art can thus be cleaned. A removal of contaminations of virtually the entire surface of the optical element can thus be carried out, whereas the state of the art only allows a cleaning/decontamination of certain areas.

In accordance with the invention, an arrangement of at least 2 up to 50 UV-LEDs for example can be used as semiconductor light sources for at least one surface of an optical element. Arrangements have proven to be especially preferable with 16 to 32 UV-LEDs (i.e. 3.2 to 6.4 watts should be sufficient). The stated number of the semiconductor light sources used in accordance with the invention, and especially UV-LEDs, shall thus not be limited in any way, but shall only be understood as an example. It is understood that no upper limit can be mentioned which arises on a case to case basis for each optical element, and can easily be determined and optionally optimized by the person skilled in the art.

These arrangements of semiconductor light sources are arranged preferably symmetrically around the optical element in order to generate the most even high light intensity over the entire irradiated surface. As already mentioned above, asymmetrical configurations can offer advantages.

The semiconductor light sources used in accordance with the invention can be composed in an arrangement for each special optical element and can be adjusted in order to fulfill the requirements placed on decontamination to a high degree without causing any likelihood of damage for the surface of an optical element. Furthermore, the wavelength can be chosen in such a way that problems concerning the destruction of material such as compaction are minimized, and are excluded in particular. Preferably, a wavelength is chosen which is close to the wavelength with which the optical system or partial system works.

It is understood that the arrangement of the semiconductor light sources on and/or about the optical element(s) is chosen at will and will be adjusted to an optimal decontamination effect, but that they should not be situated in the beam path of the light source(s) with which the optical system or partial system works in which the optical element(s) is/are used. In a projection system the beam path of the light source with system or partial system works are the light path which images the object in the object plane via one or more optical elements into the image plane.

The term “optical element” shall not be especially limited within the terms of the invention and shall comprise all optical elements known to the person skilled in the art. For example, the optical element can be a reflective optical element such as a plane mirror, a spherical mirror, a grating, an optical element with raster elements, with the raster elements consisting of the same mirrors, generally a mirror with rotation- or translation-invariant behavior. The optical element can also be a transmissive optical element such as a filter element or a refractive optical element. Refractive optical elements can be a plane plate, a positive or negative plane lens, an optical element with raster elements, with the raster elements consisting of lenses for example, a beam splitter or generally a refractive element with a rotation- or translation-invariant behavior.

The term optical element especially also comprises lenses which are used in microlithography projection systems, especially illumination systems or projection system.

Illumination systems especially for microlithography are known from a large variety of publications such as U.S. Pat. No. 6,636,367 or U.S. Pat. No. 6,333,777. Such microlithography projection systems, especially illumination systems comprise field planes and optionally several field planes conjugated with respect to the same, and a pupil plane and optionally several pupil planes conjugated with respect to the same. A lens or mirror which is arranged close to the field plane or close to a conjugated field plane in an illumination system is called a lens or mirror situated close to the field. A lens situated close to the field plane can be used to influence the evenness of illumination which is also known as uniformity. It is thus possible to additionally use the removal of contaminations on one or several lenses situated close to the field as a corrective for uniformity. Furthermore if a lens is arranged close to a field plane such a lens can be illuminated in a non-rotational symmetric manner in case a field such as a ring field is illuminated off-axis e.g. off to the axis of the projection system.

A lens or mirror which is arranged close to the pupil plane or a conjugated pupil plane is called a lens or mirror situated close to the pupil. Regarding the definition of the pupil plane one can distinguish between purely catoptric systems and dioptric or catdioptric systems. In catoptric systems, i.e. system with only reflective components the pupil plane is perpendicular to the optical axis e.g. of a projection system and comprises the intersection point of the chief ray to the central field point of a field to be illuminated in a field plane and a optical axis of the catoptric projection system. In a catadioptric or dioptric system comprising refractive components one can define a pupil plane as a plane which is perpendicular to an optical axis and which comprises the intersection points of chief ray associated peripheral points of a field to be illuminated in a field plane and the optical axis. In an ideal optical system there is no difference between the two different definitions of an pupil plane, since all chief rays to all field points of the field to be illuminated have the same intersection point with the optical axis of the projection system.

An optical axis is a straight line or a sequence of straight line sections, which comprise the vertices of the optical components.

If an optical component, e.g. a lens is situated directly in a pupil plane, then the principal ray height or chief ray height is zero. If a lens is situated in a position outside the pupil plane a principal ray height arises. A mirror is situated close to a pupil plane according to this invention if the chief ray height is at a maximum ±10% of the half diameter of the optical element which is used in operation at this position. With the help of the lens or mirror close to or in a pupil plane or a plane conjugated to the pupil plane it is possible to influence the telecentricity or the ellipticity of the illumination in the pupil, e.g. the exit pupil of the illumination system. That is why in the case of a lens or mirror close to the pupil the method for removing contaminations and/or heating the lens or mirror can lead to an improved telecentricity or ellipticity in the exit pupil.

The cleaning method is preferably carried out under vacuum. The chamber of the optical system or partial system can be used as a vacuum chamber in which the optical element is used, or it is possible to use a separate vacuum chamber for this purpose. Preferably, the removal of contaminations is carried out in a vacuum chamber already present in an optical system or partial system.

The cleaning/contamination method of the invention can be carried out in an optical system or partial system, especially in the operating breaks. A further option is that a cleaning can also be carried parallel during the operation of the optical system or partial system, e.g. parallel to a wafer exposure process. As long as the light of the semiconductor light sources does not arrive as stray light on the wafer, it is also possible to clean during the operation. It is also possible to remove the optical element(s), which are then subjected to a cleaning/decontamination method separately. Preferably, the cleaning/decontamination method occurs in one or several optical elements built into an optical system or partial system. The cleaning method can also be carried out with or on several optical elements simultaneously. The heating of the optical elements for compensating image errors or aberrations by the additional semiconductor light sources is preferably carried out during the operation of the microlithography exposure apparatus; i.e. during the exposure of the light sensitive substrate situated in the image plane of the system.

According to the method in accordance with the invention or the optical system or partial system in accordance with the invention it is also possible to measure the extent of contaminations on the optical element at first and then perform the removal of the contaminations in a purposeful manner based on the measured degree of contaminations. This can occur for example with a separate measuring apparatus which is used prior to performing the cleaning, but can also be used during the cleaning for a controlled running of and/or for determining the duration of the cleaning process.

Alternatively if the method is applied in accordance with the invention for compensating image errors by additional heating with the additional semiconductors light sources also the image errors could be measured and from that value the additional heating necessary to reduce the image errors could be calculated. Reference is made in this respect to U.S. Pat. No. 5,805,273, the content of which is enclosed herein in its entirety.

The time interval for performing the methods in accordance with the invention is not limited in any special way and can be set depending on the degree of contamination, type of contamination, light intensity, image errors, aberrations etc. The time interval for the cleaning or the heating could be determined on a case to case basis and can be determined by the person skilled in the art easily. It is also possible to provide or several measuring apparatuses for this purpose. The measurement of the performed cleaning/decontamination and/or heating can be carried out by determining the transmission degree of a diffractive optical component or the degree of reflection of a reflective optical component. This can occur during the method for removing contaminations in order to determine when the cleaning is completed, and/or before or after performing the method.

In a most preferred embodiment of the invention the additional semiconductor light sources could be used for cleaning e.g. when the microlithography projection apparatus is out of operation and/or during operation. Furthermore the additional heating of the lenses or mirrors in order to compensate for image errors can be performed out of operation and/or during operation.

Especially in the case of the removal of contaminations or heating of refractive optical elements, and lenses in particular, both surfaces of the refractive optical element are relieved of contaminations or heated. This can occur for example by an arrangement of semiconductor light sources which are arranged in and/or on a support of the optical element and/or close to the same. Both arrangements irradiate the respective surface of the optical element simultaneously or successively. It is also possible to provide only one arrangement with a suitable number of semiconductor light sources which by respective successive displacement can decontaminate or heat both surfaces of the same optical element.

Merely as an example a configuration is mentioned of at least 2 to 30 semiconductor light sources for example, e.g. UV-LEDs. The arrangement depends strongly on the output class of the semiconductor light sources used in accordance with the invention, e.g. LEDs. 30 LEDs can achieve sufficient cleaning or heating for example in the case of power LEDs. In the case of small LEDs operating in the mW range for example it is possible to use 1000 LEDs or more per surface area of an optical element, e.g. per lens surface area. The definition of an upper limit does not make sense.

According to a further embodiment of the invention, the optical system or partial system in accordance with the invention can comprise an optical element for beam formation which is situated downstream of the semiconductor light source, e.g. in order to perform an individually adjusted cleaning or heating. The downstream optical element can be chosen at will from the known ones and can be a DOE (diffractive optical element), an ROE (refractive optical element) or a CGH element (computer-generated hologram; a diffractive optical element).

For example, the downstream optical element can project a beam formation similar to the annular distribution of a ring onto the element to be cleaned. In this example, the edge is subjected to larger radiation intensity than the center of the optical element to be cleaned, so that cleaning can be performed in analogy to the contamination to be expected.

In addition to the removal of contaminations of optical elements or parts thereof, especially at least from the surface of an optical element, the method of the invention can also be used for correcting aberrations.

Apart from the semiconductor light sources in accordance with the invention, further means for cleaning/decontamination purposes can be provided such as a gas like an oxygen-containing, ozone-containing and/or argon-containing gas as a gas atmosphere or scavenging gas, an RS-antenna for generating a high-frequency plasma, electrodes for applying fields or even mechanical cleaning means.

Preferably, the optical system or partial system is an illumination system of a projection exposure system for example, especially for the area of microlithography. It can also be the projection system, i.e. a projection lens, especially for a projection exposure system or any other optical system or a part thereof, such that one or several optical components are arranged, so that a simple removal of contaminations can be performed prior to start-up or during operation, preferably outside of actual operation during exposure breaks.

According to a further aspect of the invention a projection system for imaging an object in an object-plane into an image in an image plane, i.e. a so called projection objective comprises at least one semiconductor light source. The semiconductor light source is an additional light source situated in the projection objective itself e.g. for cleaning and/or additional heating of optical elements in order to avoid e.g. image errors. The semiconductor light source(s) are then part of the projection system. The projection system can be a either a catoptric system, a catadioptric system or a dioptric system. A catoptric system comprises only reflective optical elements, a dioptric system comprises only refractive optical elements and a catadioptric system comprises reflective and refractive optical elements.

The method in accordance with the invention or the optical system or partial system of the invention is highly relevant especially for open systems which are more sensitive towards contamination or for the aforementioned EUV systems.

The advantages which can be achieved with the teachings in accordance with the invention are numerous:

The use of semiconductor light sources such as UV-LEDs offers the advantage especially in vacuum that by using these very special light sources with an exceptionally high service life no additional contaminations are introduced into the optical system or partial system by frequent changes of the light system. In contrast to this, other light sources such as mercury discharge lamps need to be exchanged very frequently because their service life is consistently impaired by adverse heat radiation, especially in vacuum. There is always the likelihood when they are exchanged that contaminations are introduced from the outside. Moreover, the decontamination process needs to be interrupted for the exchange.

The semiconductor light sources chosen in accordance with the invention offer the further advantage that no or only very little cooling is required which can be integrated directly for example, which is regularly not the case in other light sources used in the state of the art. Moreover, the semiconductor light sources used in accordance with the invention require exceptionally little space, need less space for the connections, and especially fewer cables than conventional light sources, and can be easily housed and arranged in virtually any optical system. The high service life of such semiconductor light sources allows performing numerous cleaning/decontamination processes without any disturbances. Moreover, the cleaning/decontamination process once introduced or the cleaning/decontamination apparatus once set up can be maintained unchanged over prolonged periods of time due to the high service life without having to intervene from the outside into the system.

A further advantage of the method in accordance with the invention and of the system or partial system in accordance with the invention is that not only one single light source is used, but a plurality of diodes are used, so that the suitable number and grouping of the light sources can be configured for each individual case, i.e. for every surface of every optical element, and for any possible configuration and geometry. This means a high flexibility in the application.

The arrangements of the semiconductor light sources can be configured in order to achieve an optical cleaning/decontamination effect or a heating effect in a relatively short time frame. The arrangements and number of the semiconductor light sources can be adjusted to every single optical element in an optical system. Several optical elements can be decontaminated or heated individually.

Finally, an optical illumination which is structured in a simple fashion can also be achieved in optical elements with large diameters, so that even boundary regions of an optical element are included for example and can thus also be cleaned.

The removal of contaminations is preferably used as the final cleaning before the illumination system is put into operation, or it can be used during the operation, especially during breaks in operation.

The cleaning/decontamination effect can moreover be accelerated by the presence of a gas, especially a strongly oxidizing gas.

Advantageous embodiments and further developments of the invention are obtained from the sub claims and from the following embodiments as described principally on the basis of the drawings. Every sub claim can be combined with the main claims or other sub claims without departing from the spirit of the invention.

### DESCRIPTION OF THE INVENTION

The enclosed figures illustrate the present inventive system or partial system and the teachings concerning the method which can be carried out in accordance with the invention without limiting them to the same.

The drawings shown in detail as an example:

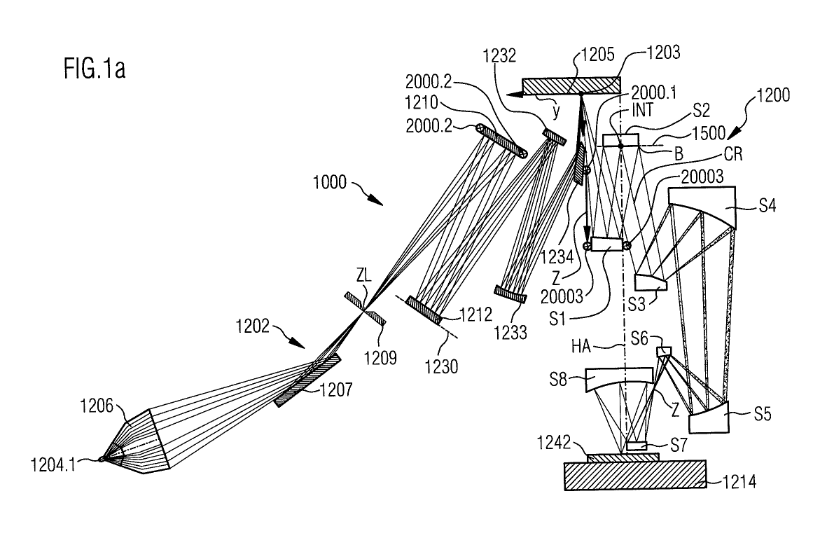

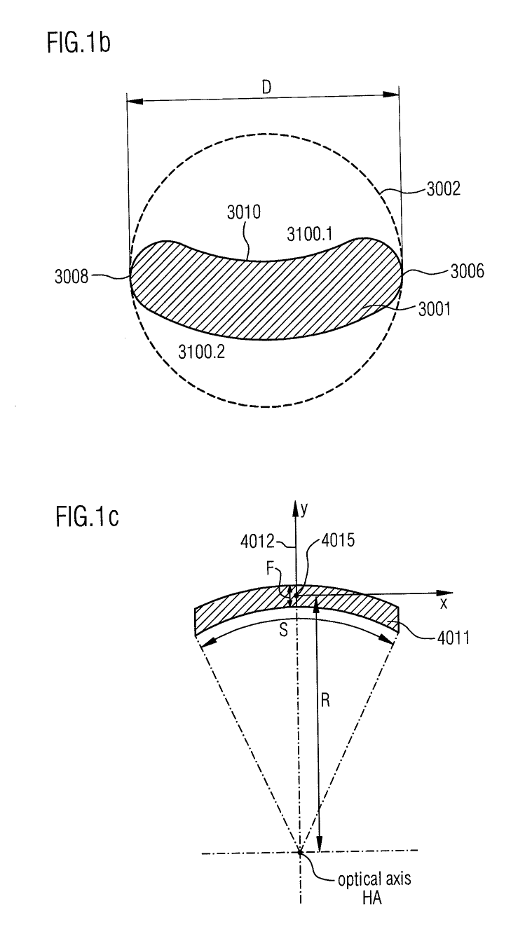

FIG. 1a shows a microlithography exposure system in an exemplary view comprising only reflective optical elements, as used e.g. in EUV lithography.

FIG. 1b shows an illuminated area on a mirror.

FIG. 1c shows a field to be illuminated in a field plane.

FIG. 1d shows a schematic illustration of a sectional view of an optical system, comprising an optical element with a support, with the semiconductor light sources being arranged in the support;

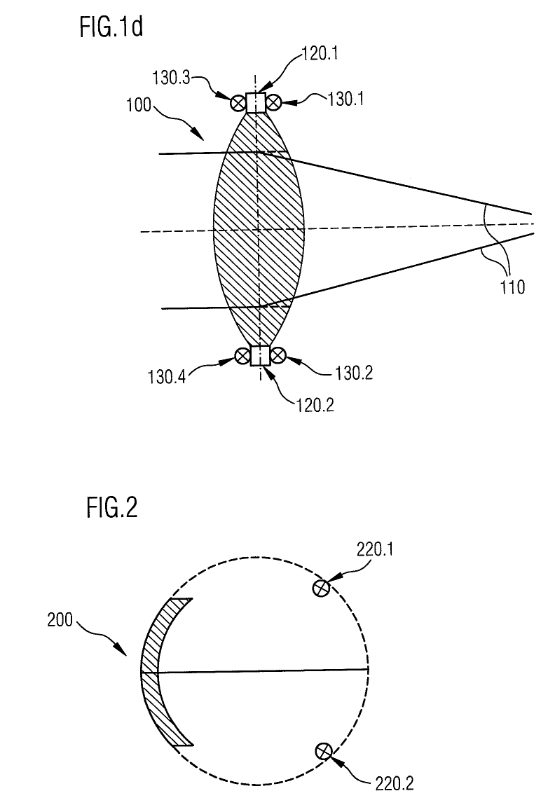

FIG. 2 shows a schematic illustration of a sectional view of an optical system, with the semiconductor light sources being situated close to the optical element;

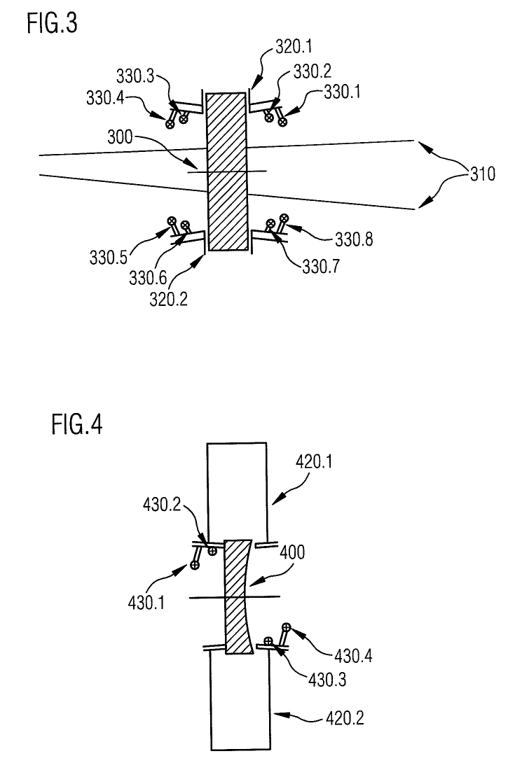

FIG. 3 shows a schematic illustration of a transmissive plane plate, with the semiconductor light sources being arranged on the support.

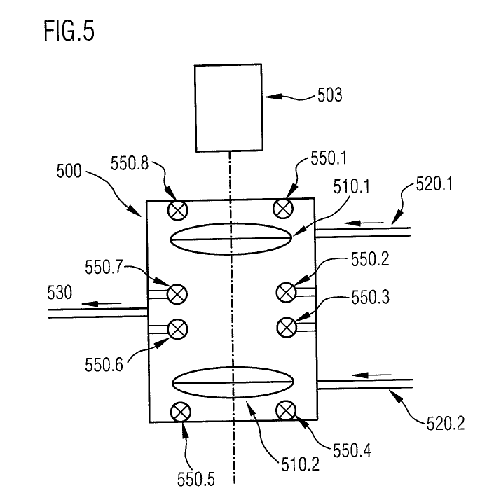

FIG. 4 shows a schematic illustration of a transmissive plane convex lens, with the semiconductor light sources being arranged on the supports;

FIG. 5 shows a schematic illustration of a sectional view of an optical system, comprising two lenses as optical elements, with the semiconductor light sources being situated close to the lenses;

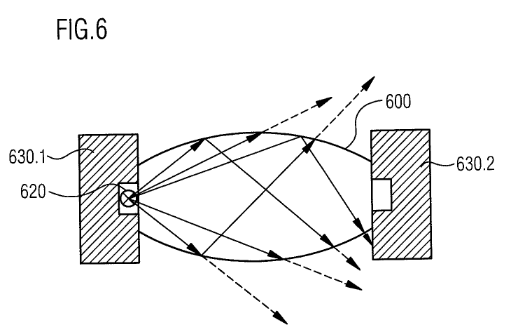

FIG. 6 shows a schematic illustration of a sectional view of an optical system, with the feeding of the light occurring on the collar of lenses;

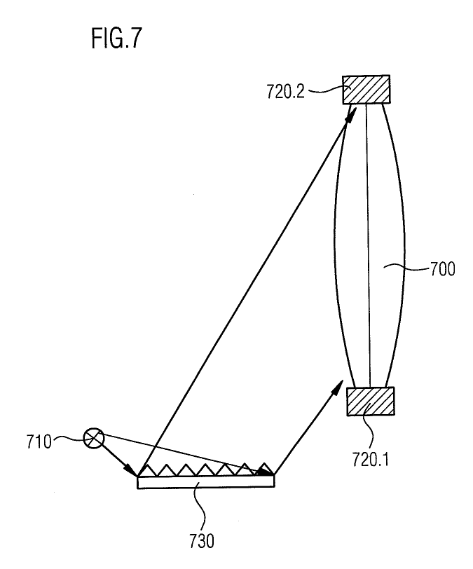

FIG. 7 shows a schematic illustration of a sectional view of an optical system, comprising a diffractive optical element in reflection for producing individual spatially resolved cleaning;

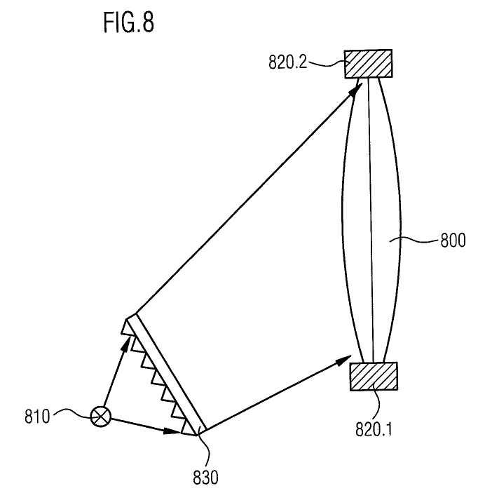

FIG. 8 shows a schematic illustration of a sectional view of an optical system as shown in FIG. 7, but with an optical element for beam formation in transmission.

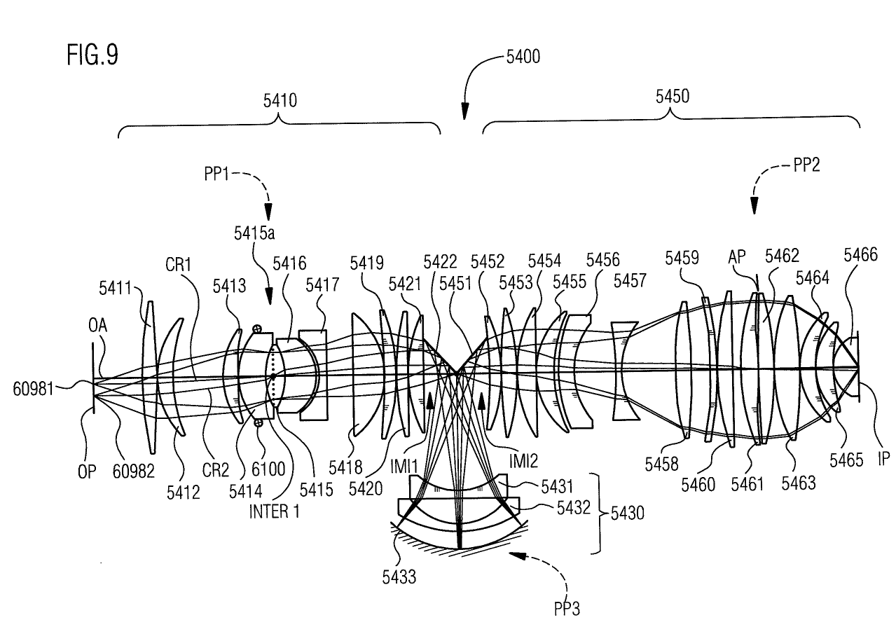

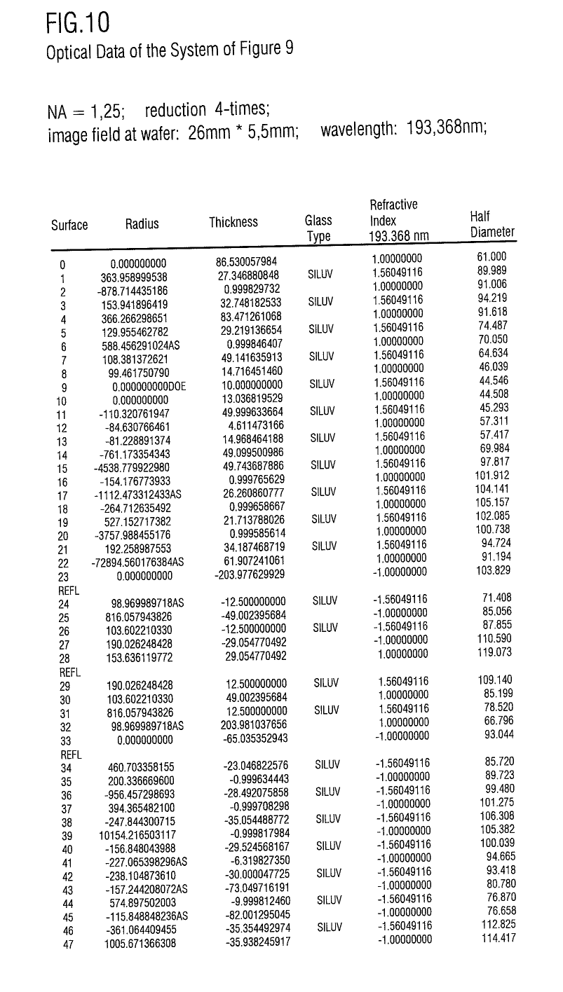

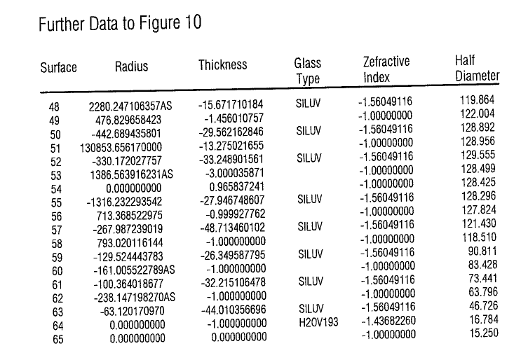

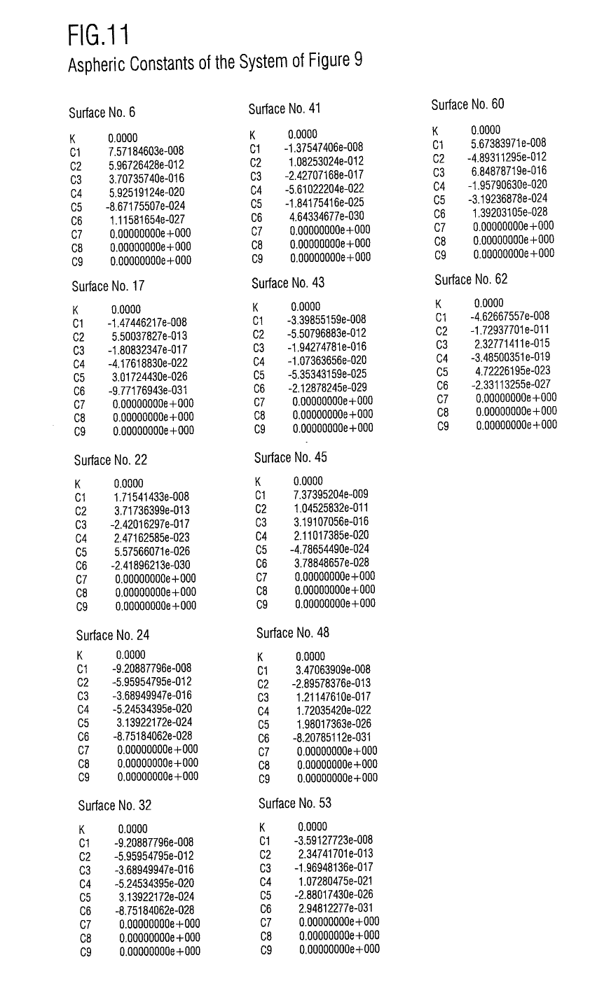

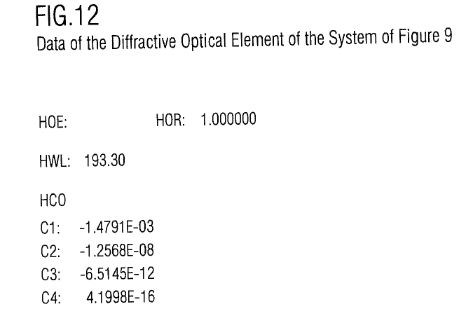

FIG. 9 shows a catadioptric projection lens for imaging an object in an object plane into an image in an image plane comprising refractive and reflective optical elements as well as diffractive optical elements arranged in or close a pupil plane to FIG. 9.

FIG. 10 show the optical data of the system according to FIG. 9.

FIG. 11 show the aspheric constants of the system according to FIG. 9.

FIG. 12 show the data of the diffractive optical element/DOE) of FIG. 9

FIG. 1a shows an example for a projection exposure apparatus for microlithography using EUV-wavelengths in the region from 11 mm to 15 mm, having an illumination system 1100 and a projection system or projection objective 1200 having eight used areas 1200 or mirrors. The projection exposure apparatus is a catoptric system comprising only reflective components.

In the embodiment shown in FIG. 1a, the projection exposure apparatus 1000 comprises a radiation source 1204.1, which emits light for illuminating an object, e.g. a structured mask 1205 in an object plane 1203. The light of the radiation source 1204.1 images the object onto a light sensitive layer 1242 situated in an image plane 1214 of the projection objective 1200.

The light of the radiation source 1204.1 is guided with the aid of an illumination system 1202 into the object plane of the projection system of the projection exposure apparatus and illuminates a field in the object plane 1203. The field in the object plane 1203 has a shape as shown in FIG. 1b.

The illumination system 1202 may be implemented as described, for example, in WO 2005/015314 having the title “illumination system, in particular for EUV lithography”.

According to the present invention, the illumination system preferably illuminates a field in the object plane of the projection objective or projection system.

The collector 1206 is a grazing-incidence collector as is known, for example, from WO02/065482A2. After the collector 1206 in the light path, a grid spectral filter 1207 is situated, which, together with the stop 1209 in proximity to the intermediate image ZL of the light source 1204.1, is used for the purpose of filtering out undesired radiation having wavelengths not equal to the used wavelength of 13.5 nm, for example, and preventing it from entering into the illumination system behind the stop.

A first optical raster element 1210 having 122 first raster elements, for example, is situated behind the stop. The first raster elements provides for secondary light sources in a plane 1230. The plane 1230 is a conjugated pupil plane of the exit pupil of the illumination system. A second optical element 1212 having second raster elements, which, together with the optical elements 1232, 1233, and 1234 following the second raster element in the light path illuminates a field in a field plane which is coincident with the object plane 1203 of the projection objective 1200. In order to improve the uniformity the optical element 1234 situated near the field-plane 1203 could be cleaned by the semiconductor light sources 2000.1 mounted on the mounting of mirror 1233. By additional semiconductor light sources 2000.2 mounted on the mounting of facetted mirror 1210 the second optical element 1212 situated near a conjugated pupil plane 1230 could be cleaned and thus ellipticity and telecentricity of the pupil illumination could be improved The second optical element having second raster elements is situated in proximity to or in the conjugated pupil plane 1230, in which the secondary light sources are provided. For example, a structured mask 1205, the reticle, is situated in the object plane 1203 of the projection system, which is imaged with the aid of the projection system 1200 using the light of the light source 1204.1 into an image plane 1214 of the projection system 1200. A substrate having a light-sensitive layer 1242 is situated in the image plane 1214. The substrate having a light-sensitive layer may be structured through subsequent exposure and development processes, resulting in a microelectronic component, for example, such as a wafer having multiple electrical circuits. In the field plane the y- and z-direction of a x-, y-, z-coordinate system with its origin in the central field point is shown.

As is apparent from FIG. 1a for lithography with wavelengths <100 nm, especially with wavelengths of e.g. 13.5 nm for EUV lithography not only the projection system is a catoptric optical system but also the illumination system is a catoptric optical system. In a catoptric optical system reflective optical components such as e.g. mirrors are guiding the light e.g. from an object plane to an image plane. In a catoptric illumination system the optical components of the illumination system are reflective. In such a system the optical elements 1232, 1233, 1234 are mirrors, the first optical element 1210 having first raster elements is a first optical element having a plurality of first mirror facets as first raster elements and the second optical element 1212 having second raster elements is a second optical element having second mirror facets.

The microlithography projection system 1200 is most preferably a catoptric projection system having eight mirrors.

The projection system 1200 illustrated in FIG. 1 comprises a total of 8 mirrors, a first mirror S1, a second mirror S2, a third mirror S3, a fourth mirror S4, a fifth mirror S5, a sixth mirror S6, a seventh mirror S7, and an eighth mirror S8. In order to remove contaminations and/or heat from the optical elements and/or influence the illumination in the pupil plane (e.g. ellipticity and telecentricty) the mirror S1 could comprises a further semiconductor light source 2000.3. The further semiconductor light source 2000.3 illuminates the mirror S2 with additional UV light. The mirror S2 is arranged in a pupil plane of the projection system. The pupil plane 1500 according to the invention is perpendicular to the optical axis HA of the illumination system and comprises the intersection point INT of the chief ray CR to the central field point of the field shown in FIG. 1c with the optical axis HA.

The uniformity of a field illumination is defined as follows:

$$uniformity [ \% ] = \frac{{SE}_{Max} ( x ) - {SE}_{Min} ( x )}{{SE}_{Max} ( x ) + {SE}_{Min} ( x )}$$

with
SE_{Max}: maximum integrated scan energy along a scan-path in scanning direction
SE_{Min}: minimum integrated scan energy along a scan-path in scanning direction

Ellipticity shall be understood in the present application as the weighting of the energy distribution in the pupil. When the energy is distributed in the pupil over the angular range of coordinates u, v, then the pupil is broken down into eight equal angular ranges Q1, Q2, Q3, Q4, Q5, Q6, Q7, Q8. The energy content in the respective angular range is obtained by integration over the respective angular range. I1 for example designates the energy content of angular range Q1. The following therefore applies to I1:

$$I 1 = {\int }_{Q 1} E ( u , v ) d u d v$$

with E(u,v) being the intensity distribution in the pupil. If a optical component is heated in a symmetric way or contaminated, then the intensity E(U,V) is changed and thus the ellipticity. Therefore e.g. by cleaning a optical component or optical element according the invention elliptocity can be influenced.

The following variable is designated as −45°/45° ellipticity:

$${E}_{- 45 ° / 45 °} = \frac{I 1 + I 2 + I 5 + I 6}{I 3 + I 4 + I 7 + I 8}$$

and the following variable as 0°/90° ellipticity:

$${E}_{0 ° / 90 °} = \frac{I 1 + I 8 + I 4 + I 5}{I 2 + I 3 + I 6 + I 6}$$

Here I1, I2, I3, I4, I5, I6, I7, I8 are the energy content as defined above in the respective angular ranges Q1, Q2, Q3, Q4, Q5, Q6, Q7 and Q8.

A principal ray or a chief ray of a light bundle is defined further in each field point of the illuminated field as shown in FIG. 1c. The principal ray or a chief ray is the energy-weighted direction of the light bundle starting from a field point.

The deviation of the principal ray or chief ray associated to a certain field point from the chief ray CR to the central filed point of the field to be illuminated in the field plane is the so-called telecentric error. The following applies to the telecentric error:

$$\vec{s} ( x , y ) = \frac{1}{N} \int d u d v ( \begin{matrix}u \\ v\end{matrix} ) E ( u , v , x , y )$$

with N normalizing the vector s(x,y) which indicates the direction of the principal ray. E (u,v,x,y) is the energy distribution depending on the field coordinates x, y in the field plane 129 and the pupil coordinates u, v in the exit pupil plane 140. The telecentric error is a measure for the telecentricity of the system

FIG. 1b shows, as an example of an illuminated area 3001 on a mirror surface of a mirror of the projection objective. The illuminated area is also denoted as footprint. The footprint has a non rotational shape. A footprint of this type is expected for some of the used areas when the projection system according to the present invention is used in a microlithography projection exposure apparatus. The envelope circle 3002 completely encloses the footprint and is coincident with the edge 3010 of the footprint at two points 3006, 3008. The envelope circle is always the smallest circle which encloses the used area. The diameter D of the used area then results from the diameter of the envelope circle 3002. The illuminated area on a mirror can have other shapes then the shape shown, e.g. a circular shape.

As is clear from FIG. 1b the illumination of a mirror shown is not circular and leads to a non-symmetric rotational heat load on the mirror surface. By illuminating the mirror surface with the light of an additional semiconductor light source, heat can selectively additionally be provided e.g. in areas 3100.1 and 3100.2. Due to the additional heat created in those areas a rotational heat load on the mirror surface can be provided and image errors can be compensated for. This is especially necessary for illumination settings, such as dipole settings, when an optical element, such as mirror S2 in the example shown is situated in or near the pupil plane. A dipole setting provides for a highly unsymmetric, in particular non rotationally symmetric heat distribution on the mirror S2. This influences the imaging quality of mirror M2. By additional semiconductor light sources 2000.3 a rotational symmetric heat distribution and therefore a better image quality can be achieved.

FIG. 1c illustrates for example the object field 11 of an EUV projection exposure apparatus in the object plane of the projection objective, which is imaged with the aid of the projection system in an image plane, in which a light-sensitive object, such as a wafer, is situated. The shape of the image field corresponds to that of the object field. With reduction projection systems, as are frequently used in microlithography, the image field is reduced by a predetermined factor in relation to the object field, for example by a factor of 4 for a 4:1—projection system or a factor of 5 for a 5:1—projection system for an microlithography projection apparatus, the object field 4011 has the form of a segment of a ring field.

The segment of the ring field 4011 has an axis of symmetry 4012. Furthermore, the x- and the y-axis of a x-, y-, z-coordinate system in the central field point 4015 spanning the object plane and the image plane are shown in FIG. 1c. As may be seen from FIG. 1c, the axis of symmetry 4012 of the ring field 4011 runs in a direction parallel to the y-axis. At the same time, the y-axis is coincident with the scanning direction of a microlithography projection exposure apparatus which is laid out as a ring field scanner. The y-direction is then coincident with the scanning direction of the ring field scanner. The x-direction is the direction which is perpendicular to the scanning direction within the object plane.

FIG. 1d shows in an embodiment in accordance with the invention a lens 100 which is part of a refractive configured optical partial system in a sectional view. The beams 110 meet the refractive optical element, which in this case is the lens 100, and pass through the same. During the method in accordance with the invention for removing contaminations and/or heating, the semiconductor light sources 130.1, 130.2, 130.3 and 130.4 are switched on. They are integrated in the first socket 120.1 and integrated in the second socket 120.2.

The figure is not true to scale and shall only show schematically how the method is to be performed or how a respective optical system or partial system can be configured.

The semiconductor light sources, especially UV-LEDs 130.1 through 130.4, can be arranged in such a way that the entire surface of the optical element, which in the present case are both surfaces of lens 100, are irradiated and thus decontaminated and/or heated. The number of the UV-LEDs is not especially limited, but can be chosen for each individual case in a respective manner and a suitable arrangement can be employed.

It is understood that a person skilled in the art can also transfer the teachings given for refractive system without any inventive action to reflective systems, and vice-versa from reflective to refractive systems, even when this is not described explicitly in individual cases. For a reflective system reference is made to FIG. 1a showing a complete catoptric microlithography projection system with reflective optical elements.

FIG. 2 shows as a further embodiment of the invention an optical component, especially a refractive or reflective optical element such as a lens or a mirror 200. The semiconductor light sources used in this example for removing contaminations are not situated in or on the support. They are arranged in the ultimate vicinity of the optical element and are shown in FIG. 2 for example as UV-LEDs and/or UV laser diodes 220.1 and 220.2.

FIG. 3 shows a further embodiment of the invention, wherein a transmissive plane plate 300 is held in a support 320.1 and 320.2, on which the beams 310 impinge during operation and which pass through the same. A large number of semiconductor light sources such as UV-LEDs 330.1, 330.2, 330.3, 330.4, 330.5, 330.6, 330.7 and 330.8 are arranged on the supports 320.1 and 320.2. For removing the contaminations, they are activated over a desired period of time, as a result of which the contaminations on one or both surfaces of the transmissive plane plate 300 are removed. It is usually not sufficient that the cleaning light meets one of the two surfaces of the optical element in order to clean both surfaces, so that in the case of a transmissive optical element preferably both surfaces are cleaned. The semiconductor light sources can also be rotating or swivel able, so that the surface of a directly adjacent optical element can also be relieved of contaminations.

FIG. 4 shows a further example of an embodiment in accordance with the invention, wherein a transmissive plane convex lens 400 is provided with an upper support 420.1 and a lower support 420.2. Semiconductor light sources 430.2 and 430.3 are integrated in said supports 420.1 and 420.2, e.g. UV-LEDs and/or laser diodes or the like. Additional semiconductor light sources such as UV-LEDs 430.1 and 430.4 are further provided on the supports 420.1 and 420.2. As a result of the chosen arrangement of the semiconductor light sources, both surfaces of the lens 400 can be irradiated over the entire surface area. The semiconductor light sources, which in this case are UV-LEDs, can be stationary or movable. LEDs 430.1 and 430.4 can be arranged so as to be extensible and/or displaceable, and/or the entire LED arrangements, which are represented here by the arrangements 430.1 and 430.2 as well as 430.3 and 430.4, can be extensible and/or displaceable and/or rotating in order to enable the alternating irradiation of both surfaces of the plane convex lens 400. A rotating arrangement is advantageous in order to illuminate the entire surface area with a few semiconductor light sources or in order to decontaminate/clean several optical elements with the same arrangement.

Although only one optical element each is cleaned and/or heated by the semiconductor light sources in the above figures, it is understood that also several optical elements in an optical system or partial system can be subjected simultaneously or successively to a method for removing contaminations and/or heating. The semiconductor light sources used for this purpose can be arranged either directly on the optical element, i.e. in its support or close to the same, or they can be configured to be displaceable or rotating for at least one surface of one or several optical elements. The number of the used semiconductor light sources is not especially limited and can be chosen in a suitable manner in each individual case.

FIG. 5 describes in a representative manner a method or an optical system or partial system in accordance with the invention on the basis of several optical elements.

FIG. 5 shows a housing 500, preferably a projection system or projection objective for microlithography, as has been disclosed in U.S. Pat. No. 6,665,126 B2 or U.S. Pat. No. 5,132,845 for refractive systems or in U.S. Pat. No. 6,600,552 B2 for reflective systems, whose scope of disclosure is fully included herein by reference. In the system shown in FIG. 5 two refractive optical elements i.e. lenses 510.1 and 510.2 are arranged in an exemplary manner. During normal operation of the optical system, of which only a section is shown here schematically, a light source 503 is used for illumination, which in this case is a DUV excimer laser for example. Scavenging gas inlets 520.1 and 520.2 for introduction of gas are further provided. Similarly, a discharge of the scavenging gas occurs together with the contamination components via line 530, e.g. at the opposite side of housing 500. The housing 500 can be configured as a vacuum chamber.

The semiconductor light sources in form of semiconductor light sources such as UV-LEDs and/or laser diodes 550.1, 550.2, 550.3, 550.4, 550.5, 550.6, 550.7 and 550.8 are arranged close to lenses 510.1 and 510.2 in a stationary manner in order to clean their surface by irradiation with UV light. They can also be provided so as to be movable, e.g. on a swivel able carrier (not shown). A gas flow, e.g. ozone-containing gas or oxygen and/or argon, can be guided preferably parallel to the surfaces of lenses 510.1 and 510.2 or along the same for removing contamination components such as hydrocarbons from the close optical system. The gas flow can preferably be activated and deactivated.

As is shown in FIG. 5 or in FIG. 9 or in FIG. 1a, the semiconductor light source(s) is/are part of the projection system, i.e. the projection objective itself.

The vacuum chamber can comprise further and/or alternative means for cleaning such as an RF-antenna for generating a high frequency plasma or electrodes for applying an electric voltage. These additional or alternative means are not shown in the figure.

FIG. 6 shows an embodiment in accordance with the invention with a lens 600 as a part of an optical system in a sectional view. The injection of light occurs in this example on the collar of lenses. The semiconductor light source 620 can be integrated for this purpose in socket 630.1 and/or 630.2 for example. The present illustration only shows one semiconductor light source in one socket. A cleaning principle is realized, according to which the light is radiated from the inside in the manner of a glass rod.

FIG. 7 shows a further example of an embodiment in accordance with the invention, wherein a light source 710 such as a laser diode or LED is used via a downstream optical element such as a diffractive optical element 730 in reflection for generating e.g. an individual spatially resolved cleaning and/or heating. The optical element to be cleaned and/or heated is in the present case a lens 700 with a first socket 720.1 and as second socket 720.2, which holds or carries the lens 700 at the top or bottom in the example. It is understood that other means are also possible which are able to hold or carry an optical element. The downstream optical element 730 used for individually aligned cleaning can be any desired optical element such as a DOE (diffractive optical element), an ROE (refractive optical element) or a CGH element (computer-generated hologram; a diffractive optical element) in order to achieve an individual distribution of intensity optimized for the optical surface for cleaning.

FIG. 8 shows in a manner similar to FIG. 7 the use of an additional optical element 830 which in the present case in transmission is used for individual spatially resolved cleaning of an optical element 800. A light source 810 such as a laser diode or LED is shown and a downstream optical element, especially a refractive optical element 830 which is used for beam formation in transmission and individual spatially resolved cleaning. The optical element to be cleaned is in the present case a lens 800 with a first socket 820.1 and a second socket 820.2, which hold or carry the lens 800 at the top and bottom in the example. The optical element 830 used for individually aligned cleaning can be any desired optical element, as has already been explained in detail in FIG. 7. The downstream optical element 830 is therefore used for optimizing the cleaning.

In FIG. 9 a further embodiment of the invention are shown.

FIG. 9 shows a catadioptric projection system 5400 for projecting an object in an object plane OP into an image in a image plane IP. The design data of this projection system can be found in FIG. 10. The surface 6, 17, 22, 24, 32, 41, 43, 45, 48, 53, 60 and 62 are aspheric surfaces. The aspheric coefficients for each element is given. The aspheric coefficients for each above mentioned aspheric surface according to the well known aspheric formula are given in FIG. 11. With the associated data for those aspherical surfaces, the sagitta or rising height p(h) of their surface figures as a function of the height h may be computed employing the following equation:

p(h)=[((1/r)h²)/(1+SQRT(1−(1+K)(1/r)²h²))]+C1−h⁴+C2−h⁶+ . . . ,

where the reciprocal value (1/r) of the radius is the curvature of the surface in question at the surface vertex and h is the distance of a point thereon from the optical axis. The sagitta or rising height p(h) thus represents the distance of that point from the vertex of the surface in question, measured along the z-direction, i.e., along the optical axis. The constants K, C1, C2, etc., are listed in FIG. 11.

The projection system according to FIG. 9 comprises a first system part 5410, a second system part 5430 and a third system part 5450. The first system part 5410 comprises refractive lenses 5411-5421 and a first folding mirror 5422. The fifth lens in the embodiment shown is a parallel-sided plate. On one side of the fifth lens 5415 a diffractive optical element (DOE) 5415a is provided. The diffractive optical element 5415 is arranged in or close to a first pupil plane PP1 of the projection system. By arranging the diffractive optical element 5415a in or close to a pupil plane a reduction of the diameter of the refractive optical lenses in the projection system can be achieved. Furthermore by the diffractive optical elements positive refractive power can be provided in the system and therefore less negative Petzval curvature is need in order to provide for the Petzval correction of the system. Although the system shown comprises a DOE this optical element is not necessary to practice the invention. In an alternative embodiment a projection system can be provided without DOE. The pupil plane PP1 is given by the intersection point INTER of the principal rays or chief rays CR1, CR2 to the peripheral points 6098.1, 6098.2 of the field illuminated with the optical axis OA of the system. As shown in FIG. 9 the field to be illuminated is a off-axis field, i.e. the field is off-axis to the optical axis OA of the projection system. If the field is illuminated off-axis as shown in the example then a lens located close to the field plane e.g. the first lens 5411 is heated in a non rotational symmetric manner. By additional heating the first lens 5411 the lens can be heated in a rotational symmetric manner, thus improving the image quality.

If one wants to improve the image quality due to a non-symmetric illumination of the pupil, e.g. in case of a dipole setting, a optical element close to a pupil plane can be additionally heated by the semiconductor light sources. To heat an optical element close to the pupil plane, e.g. the diffractive optical element 5415a.semiconductor light sources 6100 are provided at the periphery of lens 5414. By the semiconductor light source 6100, e.g. a LED the diffractive optical element 5415a is illuminated. By illuminating the diffractive optical element e.g. an individual spatially resolved cleaning and/or heating can be achieved and therefore uniformity of the pupil illumination can be influenced.

The design data of the diffractive optical element 5415 are shown in FIG. 12. Specifically, the diffractive surface acting as the diffractive optical element may be described by a phase function Φ(r) according to:

$$Φ ( r ) = \frac{2 π}{λ} \cdot ( {HCO}_{1} {r}^{2} + {HCO}_{2} {r}^{4} + {HCO}_{3} {r}^{6} + … + {HCO}_{n} {r}^{2 n} )$$

wherein r=x²+y², λ=wavelength and HCON are the coefficiences of the phase function. Upon calculation of the optical effect of the diffractive optical element on rays passing the diffractive structure the law of refraction is replaced by a local lattice approximation at a diffraction order m according to:

$${n}^{′} sin Θ = n sin Θ - \frac{m λ}{2 π} \frac{d Φ ( r )}{d r}$$

The phase coefficiences (diffractive constants) are given FIG. 12. The diffractive optical element is used in first order and has positive diffractive optical power in the following sense: The lens surface carrying the diffractive structure has a certain vertex radius. A diffractive optical power is said to be positive in the considered diffraction order when the paraxial rays of a homocentric light bundle focused about the center of the vertex curvature are diffracted towards the optical axis.

In FIG. 12 furthermore the abbreviations HOR designate the diffraction order and HWL the wavelength in nm.

The diffractive optical element 5415a has a grating constant of 770 L/mm, which is equal to a grating period of 1.3 μm. The diameter of the diffractive optical element is 90 mm and the diffractive power is K≈3.3 m⁻¹, which corresponds to a focus length of f=1/K≈303 mm. In comparison to a system without a diffractive optical element the maximum diameter of the lenses can be reduced by 7%.

The first optical element images the object plane OP in a first intermediate image IMI1 which is situated in direction the light is travelling form the object side to the image side after the first folding mirror 5412. The first intermediate image is imaged by the second system part 5430 in a second intermediate image IMI2. The second system part 5430 comprises two double passed lenses 5431 and 5432 as well as a concave mirror 5433 which is situated in a third pupil plane PP3.

The second intermediate image IMI2 is imaged by the third system part 5450, which comprises the second folding mirror 5451 as well as refractive lenses 5452 to 5466 into the image plane IP. Between the image side last lens 5466 and the image plane an immersion fluid e.g. water can be provided. In the third system part a second pupil plane PP2 is provided. In the second pupil plane the aperture stop AP of the projection system is arranged.

The three pupil plane PP1, PP2, and PP3 are given by the intersection point of the chief ray CR to the central field point with the optical axis OA.

All lenses of the projection system are made of quartz glass. Alternatively a few lenses e.g. the last lens can be made of another suitable material e.g. CaF₂. Alternatively to the system shown in FIG. 4a further diffractive optical element can be arranged in the second pupil plane PP2.

The projection system shown in the FIGS. 9-12 can be used e.g. in a microlithography projection system in which a mask in the object plane of the projection system is illuminated. The pattern of the mask is imaged by the projection system into an image plane in which a light sensitive material is situated. By imaging the mask structure onto the light sensitive object and developing the same e.g. a microelectronic component can be produced.

The invention thus provides for the first time a method and/or an optical system or partial system for removing contaminations which allows decontaminating and cleaning not only of partial areas but the entire surface of optical elements, irrespective of its shape and size.

Furthermore it provides a method for heating an optical element selectively in order to compensate image errors and/or aberrations.

Furthermore a microlithography projection system is provided comprising an additional semiconductor light source such as e.g. a UV-LED. The additional semiconductor light source is not used for imaging an object in an object plane into an image in an image plane but solely e.g. for cleaning and/or heating purposes e.g. of a diffractive optical element situated in the microlithography projection system.

1. An optical system, comprising:
at least one optical element and
at least one semiconductor light source for irradiating at least one surface of the optical element,
wherein the semiconductor light source is arranged according to at least one of the following: (i) in a support of the optical element, (ii) on the support of the optical element, and (iii) in optical proximity to the optical element, and
wherein a light of the semiconductor light source impinges onto the surface of the optical element.

2. The optical system according to claim 1, wherein the semiconductor light source comprises an ultraviolet semiconductor light source selected from the group consisting of: ultraviolet light emitting diodes, laser diodes, laser diode arrays, and diode arrays.

3. The optical system according to claim 1, wherein the optical system is comprised of at least one of: an illumination system of a projection exposure system and a microscope for wafer inspection.

4. The optical system according to claim 1, wherein the optical system is comprised of a projection system of a microlithography projection exposure system.

5. The optical system according to claim 1, wherein the optical system is a partial system of an entire optical system.

6. The optical system according to claim 1, further comprising a gas inlet for at least one of cleaning gases and other cleaning agents.

7. The optical system according to claim 1, further comprising a support holding the semiconductor light source in either a stationary or a movable manner.

8. The optical system according to claim 1, wherein the semiconductor light source comprises a downstream optical element forming at least one of a cleaning beam and a heating beam.

9. The optical system according to claim 8, wherein the downstream optical element is selected from the group consisting of a diffractive optical element, a refractive optical element and a computer-generated hologram.

10. The optical system according to claim 1, further comprising means for measuring at least one of an amount of contamination and an amount of heating on the optical element, for at least one of removing the contamination and selectively heating the optical element.

11. A microlithography projection exposure system comprising at least one semiconductor light source.

12. The microlithography projection exposure system according to claim 11, further comprising an illumination system, wherein the semiconductor light source is arranged in the illumination system.

13. The microlithography projection exposure system according to claim 11, further comprising a projection system which images an object in an object plane into an image in an image plane, wherein the semiconductor light source is arranged in the projection system.

14. The microlithography projection exposure system according to claim 11, configured as an extreme ultraviolet projection exposure system, and further comprising a housing, wherein the semiconductor light source is arranged within the housing.

15. A method for removing contaminations from at least one surface of at least one optical element, comprising:
arranging at least one semiconductor light source outputting ultraviolet light in at least one of: (i) in a support of the optical element; (ii) on the support of the optical element; and (iii) in optical proximity to the optical element; and
removing the contaminations using the at least one semiconductor light source, wherein a light of the semiconductor light source impinges onto the surface of the optical element.

16. The method according to claim 15, wherein the semiconductor light source comprises an ultraviolet semiconductor light source selected from the group consisting of: ultraviolet light emitting diodes, laser diode, laser diode arrays, and diode arrays.

17. The method according to claim 15, further comprising mounting the semiconductor light source in either a stationary or a movable manner.

18. The method according to claim 15, wherein the removal of the contaminations corrects aberrations of the optical element.

19. The method according to claim 15, further comprising measuring an extent of the contamination on at least one surface of the optical element prior to the removal of the contaminations.

20. A method for compensating at least one of image errors and aberrations of at least one optical element in an imaging system, comprising:
emitting ultraviolet light from at least one semiconductor light source; and
directing the light onto the optical element for compensating the at least one of image errors and aberrations.

21. The method according to claim 20, further comprising arranging the at least one semiconductor light source according to at least one of: (i) in a support of the optical element (ii) on the support of the optical element, and (iii) proximate to the optical element, wherein the light of the semiconductor light source impinges onto at least one surface of the optical element.

22. The method according to claim 20, wherein the semiconductor light source comprises an ultraviolet semiconductor light source selected from the group consisting of: ultraviolet light emitting diodes, laser diodes, laser diode arrays, and diode arrays.

23. The method according to claim 20, further comprising: situating the optical element in or close to a field plane; and influencing a uniformity of a field illuminated in the field plane by irradiating the optical element with ultraviolet light.

24. The method according to claim 20, further comprising: situating the optical element in or close to a pupil plane; and influencing at least one of telecentricity and ellipticity of an illumination in the pupil plane by irradiating the optical element with ultraviolet light.

25. The method according to claim 20, further comprising mounting the semiconductor light source in either a stationary or a movable manner.

26. The microlithography projection exposure system according to claim 11, wherein the semiconductor light source is at least one of an integrated ultraviolet light emitting diode, and an integrated ultraviolet laser diode.
